(19) United States
(12) Patent Application Publication
(10) Pub. No.: US 2025/0219633 A1
(43) Pub. Date: Jul. 3, 2025

(54) SMART ELECTRONIC SWITCH

(71) Applicant: Infineon Technologies AG, Neubiberg (DE)

(72) Inventors: Robert Illing, Finkenstein (AT); Alexander Mayer, Treffen (AT)

(21) Appl. No.: 18/951,575

(22) Filed: Nov. 18, 2024

(30) Foreign Application Priority Data
Jan. 3, 2024 (DE) 102024100121.6

(51) Int. Cl. H03K 17/082; G01R 31/26; H03K 17/687

(52) U.S. Cl. CPC H03K 17/0822; G01R 31/2628; H03K 17/687; H03K 2217/0027

(57) ABSTRACT

An electronic device is described herein which may be used as an electronic fuse (smart fuse). The device includes an electronic switch having a load current path coupled between an output node and a supply node and configured to connect or disconnect the output node and the supply node in accordance with a control signal. The device further includes a control circuit configured to generate the control signal based on an input signal, a current sense circuit configured to provide a current sense signal that represents a load current passing through the electronic switch, and a monitoring circuit configured to generate an overcurrent signal based on the current sense signal. The overcurrent signal is indicative of whether, or not, to disconnect the output node from supply node. The control circuit is configured to operate in a normal mode, an idle mode, and in a diagnosis mode.

### TECHNICAL FIELD

The present disclosure relates to the field of smart semiconductor switches.

### BACKGROUND

Almost every electric installation (e.g. in an automobile, in a house, in industrial equipment, electric subsystems of larger installations) include one or more fuses to provide an over-current protection. Standard fuses include a piece of wire, which provides a low-ohmic current path in case the current passing through the fuse is below a nominal current. However, the piece of wire is designed to heat up and melt or vaporize when the current passing through the fuse exceeds the nominal current for a specific time. Once triggered, a fuse has to be replaced by a new one.

Today, conventional fuses are increasingly replaced by circuit breakers. A circuit breaker is an automatically operated electrical switch designed to protect an electrical circuit from damage caused by overcurrent or overload or short-circuit. Circuit breakers may include electro-mechanical relays, which are triggered to disconnect the protected circuit from the supply when an over-current (i.e. a current exceeding the nominal current) is detected. In many applications (e.g. in the on-board power supply of an automobile), circuit breakers may be implemented using an electronic switch (e.g. a MOS transistor, an IGBT or the like) which is configured to disconnect the circuit, which is to be protected, from the supply in case of an over-current. Such electronic circuit breakers may also be referred to as electronic fuses (also referred to as e-fuses or smart fuses). Besides its function as a circuit breaker, an electronic fuse may also be used to regularly switch a load on and off (e.g. for pulse-width modulated operation). Usually, the switching state (on/off) of electronic switches such as MOS transistors is controlled using so-called driver circuits or simply drivers (gate drivers in case of MOS transistors).

However, at least in some electronic fuses common driver circuits may be inadequate with regard to fault tolerance and functional safety, which may be an issue particularly in automotive applications, in which standards concerning functional safety must be complied with (e.g. ISO 26262). In fact, an electronic fuse needs more than just replacing a classical fuse by an electronic switch. A robust implementation of an electronic fuse entails various challenges. Further, the electronic fuse's own current consumption may be an issue. In particular in automotive applications (or other applications in which the power supply relies on batteries), a low power consumption of devices such as electronic fuses is a desirable design goal. To reduce power consumption, electronic fuses may be designed to operate in a special mode, in which several functions and circuits of the electronic fuse are inactive to reduce power consumption under certain circumstances (e.g. when the electronic switch in the e-fuse circuit is on, but the load current is low). Herein, this mode of operation is referred to as “idle mode”.

The very limited functionality of an electronic fuse during idle mode gives rise to further problems because certain diagnosis functions may be unavailable during idle mode and switching over to normal operation (with increased power consumption) and back to idle mode may take a relatively long time. The inventors have set themselves the object to improve existing concepts for electronic fuses with regard to the problems described above.

### SUMMARY

The object mentioned above is achieved by the electronic device of claim 1 and the method of claims 14. Various embodiments and further developments are covered by the dependent claims. Accordingly, a circuit for use as an electronic fuse is described herein.

One embodiment relates to an electronic device. The device includes an electronic switch having a load current path coupled between an output node and a supply node and configured to connect or disconnect the output node and the supply node in accordance with a control signal. The device further includes a control circuit configured to generate the control signal based on an input signal, a current sense circuit configured to provide a current sense signal that represents a load current passing through the electronic switch, and a monitoring circuit configured to generate an overcurrent signal based on the current sense signal. The overcurrent signal is indicative of whether, or not, to disconnect the output node from supply node. The control circuit is configured to operate in a normal mode, an idle mode, and in a diagnosis mode. The control circuit is configured to change between normal mode and idle mode based on an idle mode condition, wherein, in idle mode, at least the monitoring circuit and the current sense circuit are inactive. The control circuit is further configured to change between idle mode and diagnosis mode based on a diagnosis enable signal, wherein, in diagnosis mode, the monitoring circuit remains inactive while the current sense circuit is active.

Another embodiment relates to a method for operating an electronic device as an electronic fuse. The method includes generating a control signal based on an input signal and connecting/disconnecting an output node and a supply node of the electronic device in accordance with the control signal using an electronic switch. The method further includes: generating, using a current sense circuit, a current sense signal that represents a load current passing through the electronic switch; monitoring the load current, using a monitoring circuit and based on the current sense signal; and generating an overcurrent signal based on the current sense signal, wherein the overcurrent signal indicates whether, or not, to disconnect the output node from the supply node. The electronic device is configured to operate in a normal mode, an idle mode, and in a diagnosis mode, wherein the method includes initiating a change between normal mode and idle mode based on an idle mode condition, wherein, in idle mode, at least the monitoring circuit and the current sense circuit are deactivated, and initiating a change between idle mode and diagnosis mode based on a diagnosis enable signal, wherein, in diagnosis mode, the monitoring circuit remains inactive while the current sense circuit is active.

### BRIEF DESCRIPTION OF THE DRAWINGS

The invention can be better understood with reference to the following drawings and descriptions. The components in the figures are not necessarily to scale; instead emphasis is placed upon illustrating the principles of the invention. Moreover, in the figures, like reference numerals designate corresponding parts. In the drawings:

FIG. 1 schematically illustrates one example of an electronic fuse circuit including an electronic switch and a control circuit configured to drive the electronic switch.

FIG. 2 illustrates the application of an electronic fuse circuit in more detail and in particular its interoperation with a controller circuit such as, for example, a microcontroller.

FIG. 3A is a diagram illustrating a family of characteristic curves (time over current) for a 0.35 mm² cable and for different maximum cable temperatures.

FIG. 3B is a diagram illustrating a family of characteristic curves (time over current) for a maximum cable temperature of 25 Kelvin above ambient temperature and for different cable cross-sections.

FIG. 4 illustrates one example of the monitoring circuit (smart fuse function) used in the example of FIG. 1.

FIG. 5 is an exemplary state diagram showing different modes of operation (states) of control circuit and electronic fuse included in the electronic fuse.

FIG. 6 illustrates a modification of the example of FIG. 1.

FIG. 7 is a timing diagram illustrating the smart fuse function implemented by, e.g., the circuits of FIGS. 1 and 6 in more detail.

### DETAILED DESCRIPTION

In the following detailed description, reference is made to the accompanying drawings. The drawings form a part of the description and, for the purpose of illustration, show examples of how the embodiments may be used and implemented. It is to be understood that the features of the various embodiments described herein may be combined with each other, unless specifically noted otherwise.

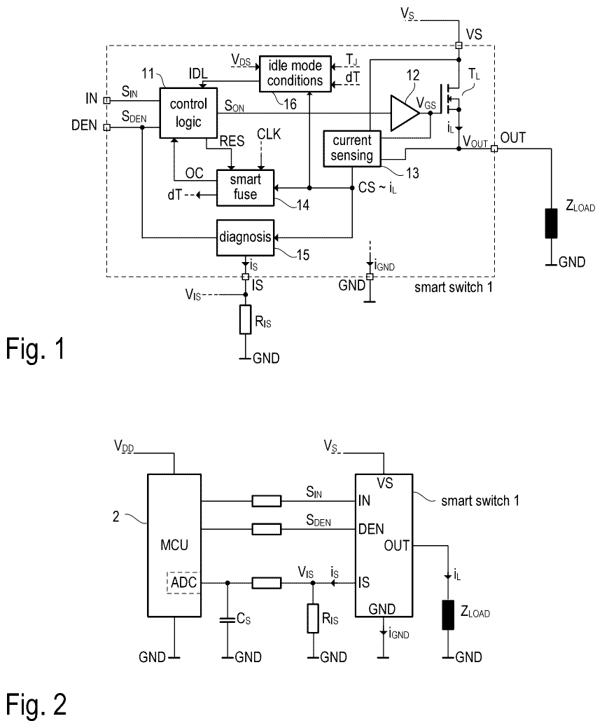

FIG. 1 illustrates an example of an electronic fuse circuit (smart switch device 1) including an electronic switch T_{L} and a control circuit configured to drive the electronic switch T_{L}. In the present example, the electronic switch is an n-channel MOS (metal-oxide-semiconductor) field-effect transistor (MOSFET). It is understood that other types of transistors may be used instead of an n-channel MOSFET. In the depicted example. The electronic switch T_{L} has a load current path (i.e. a drain-source current path in case of a MOSFET) which is coupled between an output node OUT and a supply node VS of the electronic fuse circuit. Accordingly, the electronic switch is configured to connect the output node OUT with the supply node VS (and disconnect the output node OUT from the supply node VS) in accordance with a control signal S_{ON}. The control signal S_{ON} is a logic signal that is generated by a control circuit 11 based on an input signal S_{IN}, which can be regarded as a switch-on/switch-off command. The control signal S_{ON} can assume a High level (S_{ON}=1) or a Low level (S_{ON}=0), wherein a High level may indicate that the electronic switch T_{L} is to be switched on and a Low level may indicate that the electronic switch T_{L} is to be switched off. Dependent on the actual implementation a gate driver circuit 12 may be connected between the control logic 11 and the control electrode (gate electrode in case of a MOSFET) of the electronic switch T_{L}, wherein the gate driver circuit 12 is configured to generate, based on the logic signal S_{ON}, for example, a suitable gate-source voltage VGS (or gate current i_{G}) for switching the MOSFET T_{L} on and off. Various suitable implementations of gate driver circuits are as such known and thus not further discussed herein.

The e-fuse circuit (smart switch device 1) further includes a current sense circuit 13 configured to provide a current sense signal CS that represents a load current i_{L} passing through the electronic switch T_{L}. Various different types of current sense circuits are as such known and thus not further discussed herein in more detail. In one example, the current sense circuit includes a so-called sense transistor which is operated in the same operating point as the MOSFET T_{L} and thus provides a sense current i_{CS} that is proportional to the load current i_{L}. In one example, the MOSFET T_{L} is implemented using a plurality of transistor cells (cell array), wherein transistor cells of the cell array are used to implement the sense transistor. The ratio i_{CS}/i_{L} is then approximately equal to the ratio of transistor cells of sense transistor and load transistor T_{L}. In some embodiments, the current sense signal CS may be a digital signal. In this case the current sense circuit 13 performs an analog-to-digital conversion.

The actual fuse function is implemented by the monitoring circuit 14, which is labelled “smart fuse” in FIG. 1. The monitoring circuit 13 determines, based on the current sense signal CS, an overcurrent signal OC, which is indicative of whether to disconnect the output node OUT from supply node VS (by opening the electronic switch T_{L}). The overcurrent signal OC may supplied to the control logic 11 which is configured to set the logic signal S_{ON} to a Low level when the overcurrent signal OC indicates a switch-off of the electronic switch T_{L}.

In one example, the monitoring circuit is configured to generate the overcurrent signal OC based on the current sense signal CS and at least one wire parameter that characterizes a wire/cable connected between the output node OUT and the electric load Z_{LOAD} during operation. The at least one wire parameter may include a wire cross-section area A (in mm²) and a temperature threshold dT_{R} (in K) representing the allowed maximum temperature difference between ambient temperature and cable temperature. The wire diameter (or any other parameter representing the size of the wire) may be used instead of the cross section area. In this embodiment, the monitoring circuit 14 may be configured to estimate, based on the current sense signal CS and the mentioned wire parameter(s), the temperature difference dT between the cable and ambient temperature. If the estimated temperature dT reaches or exceeds the temperature threshold dT_{R} the monitoring circuit 14 may signal an overcurrent by setting the overcurrent signal OC to a High level (OC=1). Various suitable implementations of the monitoring circuit 14 are as such known. One example is described in the publication U.S. Pat. No. 10,965,120 B2.

In the example of FIG. 1 the input signal S_{IN} is a logic signal received at an input pin IN from an external controller (see also FIG. 2). In other embodiments, the input signal S_{IN} may be received via a digital communication interface such as, for example, the Serial Peripheral Interface (SPI). In one embodiment, the input signal S_{IN} may be generated (e.g. by the communication interface) based on a command received via a bus line connected to the digital communication interface. In case of an SPI the bus line may be the so-called MOSI (Master-Out/Slave-In) line. In the example of FIG. 1, another logic signal S_{DEN} is received, from the external controller, at a further input pin DEN. The signal S_{DEN} is also referred to as diagnosis enable signal. The electronic fuse circuit also includes a diagnosis circuit 15 which is activated and deactivated in accordance with the diagnosis enable signal S_{DEN}. In the example of FIG. 1, the diagnosis circuit 15 receives the diagnosis enable signal S_{DEN}. Alternatively, the diagnosis circuit 15 may activated and deactivated by the control logic 11 dependent of the logic level of the diagnosis enable signal S_{DEN}.

The diagnosis circuit 15 is configured to output a signal i_{S} (diagnosis output signal) which is based on the current sense signal CS when the diagnosis enable signal S_{DEN} causes an activation of the diagnosis circuit 15. In the depicted example, the diagnosis output signal i_{S} is output at chip pin IS, which is connected to a reference potential (e.g. ground) via a resistor R_{IS}. Accordingly, the diagnosis output signal i_{S} is drained via the resistor R_{IS} thereby causing a voltage drop V_{IS}=R_{IS}·i_{S} across the resistor R_{IS}. This voltage drop V_{IS} may be sensed and evaluated, e.g., by an external controller (see also FIG. 2).

If the current sense signal CS is a digital signal, the diagnosis circuit 15 may include a digital-to-analog converter (DAC) with current output, wherein the DAC generates the diagnosis output signal i_{S} based on the digital signal CS. It is noted that the diagnosis circuit 15 may not only be configured to output load current information but also additional information. In some embodiments, the diagnosis output signal i_{S} may include a temperature information or indicate an error or the like. The diagnosis circuit 15 may select the information to be output (as signal i_{S}) dependent on the signal S_{DEN}, which may be modulated in different ways. In another example, the diagnosis enable signal may be received via the digital communication link (e.g. an SPI bus). In this case, the signal S_{DEN} may be a digital signal indicating which type of information is to be output at the pin IS. In some embodiments, the diagnosis output signal is not a current signal like in FIG. 1 but rather a digital signal that is transmitted, e.g., to an external controller via the digital communication link (e.g. the MISO (Master-In/Slave-Out) line in case of SPI).

In the example of FIG. 1, the electronic fuse circuit has a ground pin GND, which is connected (optionally via a low-ohmic resistor) to ground potential during operation, The current i_{GND} drained via the ground pin represents the current consumption of the electronic fuse itself, i.e. the total current consumption of the circuit components included in the electronic fuse circuit (denoted as smart switch 1 in FIG. 1). During normal operation (normal mode), when all components such as the current sense circuit 13, the monitoring circuit 15, etc. are active, the current i_{GND} may be quite significant, e.g. in the range of milliamperes (e.g. 20 mA to give an example). Even in a situation, in which the electric load Z_{LOAD} is inactive and the load current i_{L} is very low or even zero, the smart switch device 1 cannot be simply switched off to reduce the current consumption (current i_{GND}), because when used as an electronic fuse, the smart switch must normally be switched on in order to apply the supply voltage to the load Z_{LOAD}. In applications, in which a plurality of electronic fuses are used (such as in automotive applications), the total current consumption of all electronic fuses may easily add up to values of several hundred milliamperes or more, which is unacceptably high particularly when the power supply is provided by a battery.

To reduce the power consumption of smart switches (although switched on), a so-called idle mode has been introduced, in which many internal components of the smart switch are inactive to reduce the current consumption i_{GND}. In the examples described herein, at least the monitoring circuit 14 and the current sense circuit 13 are inactive when the smart switch operates in idle mode. The mode of operation is controlled by the control logic 11 (or parts thereof). Accordingly, the control circuit 11 is configured to change from operation in normal mode to idle mode (and vice versa) based on an idle mode condition. Although not explicitly shown in FIG. 1, the control logic 11 may be configured to activate and deactivate certain components of the smart switch upon a mode change. In the example of FIG. 1, the evaluation circuit 16 detects whether the idle mode condition is fulfilled and generates a respective logic signal IDL which is supplied to the control logic 11. That is, the signal IDL indicates whether, or not, the idle mode condition is fulfilled.

In a simple example, the idle mode condition is i_{L}<i_{IDLE}, wherein i_{IDLE} is a current threshold. That is, the idle mode condition is fulfilled when the load current i_{L} is lower than the threshold i_{IDLE}. In another example, the idle mode condition is i_{L}<i_{IDLE} & T_{J}<T_{JMAX}, wherein T_{J} is a measured temperature of the transistor T_{L} and T_{JMAX} is a respective temperature threshold. That is, the idle mode condition is fulfilled when the load current i_{L} is lower than the current threshold i_{IDLE} and the junction temperature T_{J} of the transistor is below the temperature threshold T_{JMAX}. In other embodiments, more than two criteria may be combined (using an and-conjunction) to define the idle mode condition. In the depicted example, the estimated wire temperature dT (provided by the monitoring circuit 14) is also considered.

In idle mode, the total power consumption i_{GND} of the smart switch device 1 can be reduced to several microamperes (e.g. 30 μA) while the transistor T_{L} is on. However, the price for this reduction is that most of the functions of the “smart functions” such as the monitoring circuit 14, the current sensing 13 and the diagnosis circuit 15 are not available. Particularly the non-availability of the diagnosis function is a problem in many applications. A straight-forward approach would be to temporarily switch from idle mode into normal mode when the diagnosis enable signal S_{DEN} indicates a request to output diagnosis information (i.e. activates the diagnosis circuit). However, if the smart switch “wakes up” and changes from idle mode into normal mode, it has to remain in normal mode for a certain time (typically 100 ms or more) before it can switch back into idle mode. This delay time is needed for various reasons. For example, when using the smart switch to drive the load Z_{LOAD} with a PWM signal (e.g. the input signal S_{IN} is modulated and the transistor T_{L} is periodically switched in and off in accordance with S_{IN}) a permanent toggling between normal mode and idle mode is avoided by the delay time. Also the restoration of required register values in the monitoring circuit 14 takes some time when changing from idle mode to normal mode. Therefore, when diagnosis information is needed during idle mode operation, a regular temporary switchover to normal mode is not an option in many applications, because, due to the relatively long time the smart switch has to remain in normal mode before switching back to idle mode, the average current consumption i_{GND} would increase significantly thereby deteriorating the advantages of the idle mode.

To address the problem discussed above, a new mode of operation is introduced, which is herein referred to as diagnosis mode. In the embodiments described herein, a change into diagnosis mode can only be achieved from idle mode. In one embodiment, the control circuit 11 is configured to change between idle mode and diagnosis mode based on the diagnosis enable signal S_{DEN}, wherein, in the diagnosis mode, the current sense circuit 13 is active (to enable the diagnosis output), whereas the monitoring circuit 14 remains inactive.

As the monitoring circuit 14 remains inactive when changing from idle mode into diagnosis mode (and back to idle mode), a temporary switchover to diagnosis mode is possible, wherein the time in diagnosis mode can be very short (significantly shorter than the 100 ms which are needed to switch into normal mode and back to idle mode). As a result, the short and temporary switchover to the diagnosis mode (in order to output diagnosis information) does not significantly increase the average of the smart switch device's own current consumption i_{GND}. Changes between idle mode and diagnosis mode do not affect the (inactive) state of the monitoring circuit 14. The monitoring circuit 14 is only activated upon a change back into normal mode, wherein the activation of the monitoring circuit entails a restoration of the previous active state of the monitoring circuit 14, in particular the restoration of the one or more internal register values of the monitoring circuit 14, which were lost when the monitoring circuit has been deactivated.

Before discussing the functions of the electronic fuse circuit (smart switch 1) in more detail, an exemplary application of the electronic fuse circuit is discussed with reference to FIG. 2, which particularly shows the interoperation of the smart switch 1 with a controller circuit 2 which may be, for example, a common microcontroller (labelled MCU in FIG. 2). The smart switch 1 of FIG. 1 may be implemented in accordance with or similar to the example of FIG. 1.

The microcontroller 2 is configured to generate the signals S_{IN} and S_{DEN} and output these at digital output pins or so-called general-purpose input/output (GPIO) pins. The respective pins of the microcontroller are connected with the input pins IN and DEN of the smart switch device 1 (e.g. via resistors). The supply pin VS is connected to the battery (e.g. to a so-called “terminal 30” (“permanent plus”) providing the battery voltage V_{S}) and the ground pin GND is connected to ground potential. The output pin OUT is connected to the load Z_{LOAD} (like in the example of FIG. 1). The diagnosis output IS is connected to ground via resistor R_{IS} (like in the example of FIG. 1) and also to an analog input (e.g. via an RC filter) of the microcontroller. The microcontroller may include an analog-to-digital converter (ADC), which is configured to digitize the voltage V_{IS}=R_{IS}·i_{S}. In this way, the micro controller can initiate a diagnosis output by outputting the diagnosis enable signal S_{DEN} and read the diagnosis information by digitizing the voltage V_{IS} which is proportional to the diagnosis current i_{S}. In the depicted example, the controller 2 is supplied by supply voltage V_{DD} which is different from the battery voltage V_{S}.

The controller 2 may include a processor with one or more processor cores that are configured to execute software instructions, which are stored in a memory of the controller 2. Together with peripheral circuits (such as the ADC, the memory, GPIO driver circuits, etc.) and the appropriate software instructions the controller is able to provide the functions necessary to control the operation of the smart switch 1. It is understood that the controller does not necessarily have to have a processor. In some embodiments the controller may include one-time programmable or hard-wired logic circuits which are, together with the mentioned peripheral circuits, configured to provide substantially the same functions as the mentioned processor. Also a combination of processor and hard wired logic is possible. Any hardware entity including a processor and/or other circuits configured to provide the functions described herein is considered a controller. Finally, it is noted that the smart switch 1 may include more than one output channel to be able to connect more than one electric load.

Before discussion the above-mentioned modes of operation (normal mode, idle mode, diagnosis mode) in more detail, the purpose and function of the monitoring circuit 14 is explained in more detail below. The monitoring circuit is one of the core functions of the electronic fuse circuit as it implements a behavior similar to that of a conventional fuse.

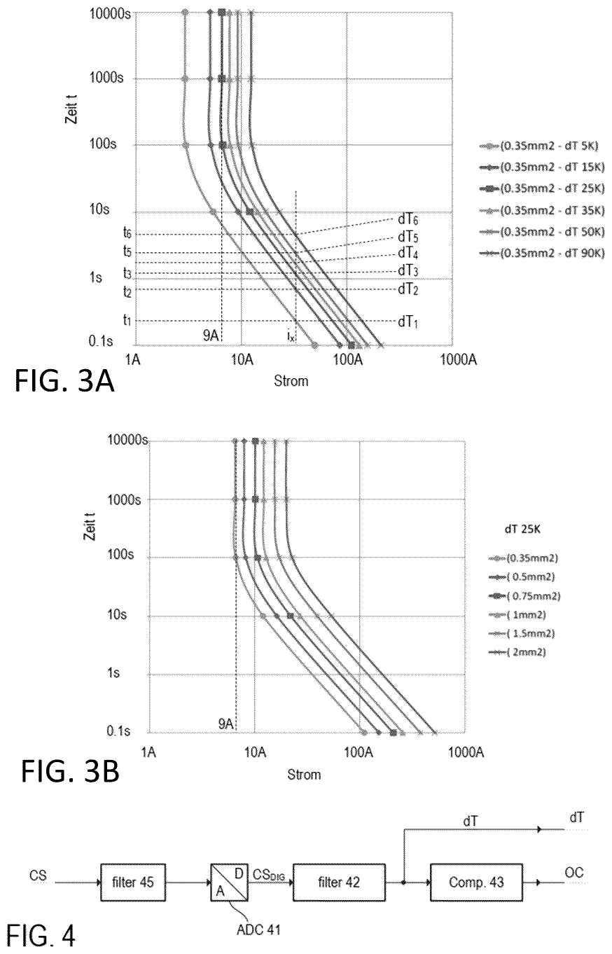

As mentioned above, the wire connecting the load Z_{LOAD} and the smart switch 1 may be selected to withstand a nominal current of the load Z_{LOAD}. The lifetime of a wire/cable depends (amongst other factors) on the wire temperature. FIGS. 3A and 3B are diagrams including a family of characteristic curves, wherein each characteristic curve is associated with a specific combination of maximum temperate difference dT (maximum temperature above ambient temperature) and cable cross section A (e.g. cross-sectional area in mm²). Each characteristic curve represents the relation between load current and the maximum allowable time period, which the wire can carry the load current without exceeding the specified temperature difference dT. FIG. 3A includes characteristic curves for various temperature differences dT and a specific cross sectional area of 0.35 mm², while FIG. 3B characteristic curves for a specific temperature differences dT of 25 K (Kelvin) and various cross sectional areas. As can be seen from FIGS. 3A and 3B, a wire with a cross-sectional area of 0.35 mm² may carry a current of approximately 9 A (amperes) for practically infinite time without exceeding a temperature difference dT of 25 K above ambient temperature. As can be seen from FIG. 3B, a wire with a cross-sectional area of 0.75 mm² may carry a current of 10 A (amperes) for approximately 100 seconds before reaching a temperature difference dT of 25 K above ambient temperature. Generally, the higher the load current, the shorter the allowable time period for a given cross-sectional area and a given temperature difference. It is noted that the characteristic curves shown in the diagrams of FIGS. 3A and 3B have a linearly falling branch in a double logarithmic representation.

As can be seen from FIGS. 3A and 3B, a temperature difference dT_{R} (e.g. temperature values dT₁, dT₂, dT₃, dT₄, dT₅, dT₆) is associated with a given integration time tₓ (e.g. times t₁, t₂, t₃, t₄, t₅, t₆) for a given current (see FIG. 3A, current iₓ) and a specific cross-sectional area (e.g. 0.35 mm² in the example of FIG. 3A). Hence, a temperature value dT (representing the temperature above ambient temperature) may be determined for a specific wire cross section by integrating the current i_{L}=iₓ passing through the wire over time, and the overcurrent signal OC may indicate a switch-off of the power transistor T_{L} when the temperature value dT reaches a defined first reference temperature difference dT_{R} (temperature threshold). The mentioned integration may be efficiently implemented using a digital filter, which may be included in the monitoring circuit 14 (see FIG. 4). One exemplary, simplified implementation of the monitoring circuit 14 is illustrated in FIG. 4.

Basically, the monitoring circuit of FIG. 4 is configured to determine the overcurrent signal OC based on the current sense signal CS. As mentioned, the integration may be accomplished in a digital filter 42 which has an integrating characteristic. According to the depicted example, the current sense signal CS, which may be a voltage that is proportional to the load current i_{L} is supplied to the input of filter 45, which may be an (optional) analog low-pass filter to remove transients or the like, which have a comparable high frequency. The output of filter 45 may be connected to the input of analog-to-digital converter (ADC) 41, which is configured to digitize the filtered current sense signal CS. If CS is already a digital signal, the filter 45 and the ADC 41 are not needed. In the present example, the ADC 41 may have a logarithmic characteristic in order to account for the logarithmic characteristic curves shown in FIGS. 3A and 3B. The (e.g. logarithmized) digital current sense signal CS_{DIG} is then converted to a temperature signal dT by digital filter 42. The resulting temperature value dT (representing a temperature difference above ambient temperature) is then supplied to digital comparator 43, which may be configured to set the overcurrent signal OC to a high-level when the temperature value dT provided at the output of digital filter 42 exceeds the reference temperature difference dT_{R} (e.g. 25 K) specified for a specific wire cross-section. It is noted that, if the ADC 41 does not have a logarithmic characteristic, the digital current sense signal CS_{DIG} should be squared before being supplied to the filter 42. Also when the current sense circuit 13 already provides a digital current sense signal, this signal is also squared before being fed into the filter 42. In this regard, reference is made to FIG. 8 as well as to publication US20170294772A1, in which this concept of temperature calculation is described.

As mentioned, the digital filter 42 is configured to convert the load current (represented by the digitized current sense signal CS_{DIG}) and an associated integration time, during which the current passes through the wire, into a temperature value dT. In the present example, the filter characteristic 42 depends on a parameter characterizing the wire, e.g. the cross-sectional area of the wire, which carries the current and which may be represented by a family of characteristic curves such as those shown in the diagram of FIG. 3A (for an exemplary cross-sectional area of 0.35 mm²). In one specific example, the characteristic curves (or related curves) may be stored as a look-up table, i.e. by storing a plurality of sampling points of the characteristic curves in a memory. Values between two sampling points may be determined using, e.g. interpolation.

Conventional fuses are produced for a specific trigger current and with a specific trigger time (slow blow fuses, medium blow fuses, fast blow fuses), wherein the trigger time corresponds to a specific combination of reference temperature dT_{R} and cross-section as explained above (see FIGS. 3A and 3B). It would be desirable, however, to have a configurable fuse, which may be used for various different wire parameters such as, for example, wire cross-sections and maximum temperature values dT_{R} (maximum temperature above ambient temperature). Therefore, the wire parameters may be configurable and set to the desired values for a specific application.

The filter 42 is a digital filter and the filter output dT depends on the internal states of the filter, which are represented by register values. These states/register values are lost (reset) when the monitoring circuit 14 is deactivated upon entry into idle mode. Therefore the control logic 11 may be configured to store these register value when changing into idle mode and restore these values when changing back into normal mode. The restoring of the register values is triggered by the signal RES shown in FIG. 1. The monitoring circuit, in particular the digital filter 42, may need a clock signal for operation which is denoted CLK in FIG. 1.

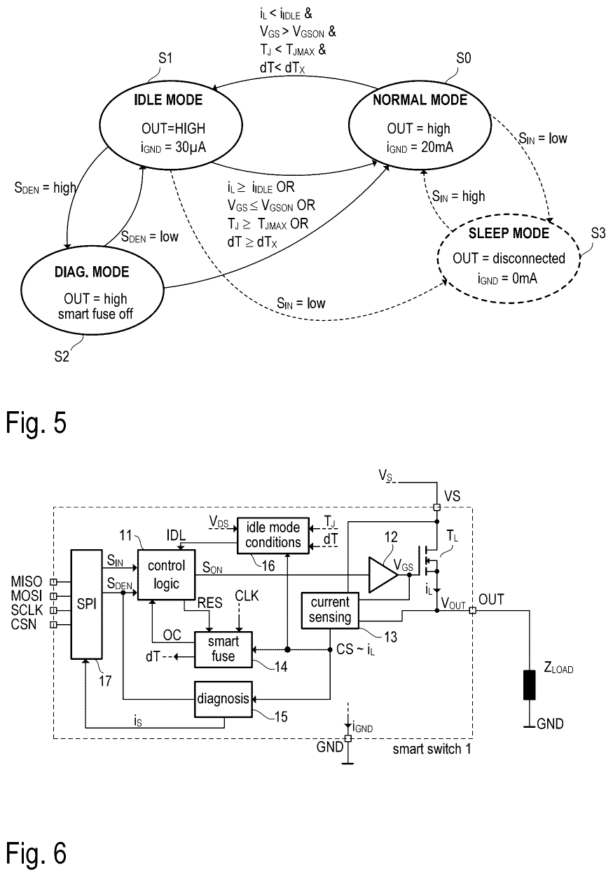

FIG. 5 is an exemplary state diagram showing the different modes of operation (states) of the control logic 11 (which determines the state of the whole electronic fuse circuit). In FIG. 5, the normal mode is denoted S0, the idle mode is denoted S1, and the diagnosis mode is denoted S2. In all three modes S0-S2 the electronic switch T_{L} is on and thus the output pin OUT is approximately at the supply voltage V_{S}. In normal mode S0, the monitoring circuit 14 and the current sense circuit 13 are active and the smart switch's own current consumption i_{GND} is in the range of milliamperes (e.g. 20 mA). In idle mode S1, the monitoring circuit 14, the current sense circuit 13, and other circuitry are inactive to reduce the current consumption to some microamperes (e.g. i_{GND}=30 μA). In the diagnosis mode S2, the monitoring circuit 14 remains inactive (and thus the register values are not restored) whereas the current sense circuit 13 is active to enable the diagnosis circuit 15 to output load current information as diagnosis information.

In the example of FIG. 5, the idle mode condition is the and-conjunction (i_{L}<i_{IDLE}) & (V_{GS}>V_{GSON}) & (T_{J}<T_{JMAX}) & (dT<dT_{X}). That is, the idle mode condition is fulfilled when (i) the load current i_{L} is small enough (below the threshold i_{IDLE}) and (ii) the transistor T_{L} is actually on (i.e. the gate-source-voltage V_{GS} is above a threshold voltage V_{GSON}) and (iii) the junction temperature T_{J} of the power transistor T_{L} is not too high (i.e. below the temperature threshold T_{JMAX} and (iv) the estimated cable temperature dT (over ambient temperature) does not exceed a threshold dT_{X}. If all criteria are met, then the smart switch device changes from normal mode S0 into idle mode S1. If one of these criteria is not met, the idle mode condition is not fulfilled anymore and the smart switch changes back to normal mode S0. It is noted that, in normal mode S0, the criterion i_{L}<i_{IDLE} may be evaluated by the circuit 16 (see FIG. 1) using the current sense signal CS. However, as this signal may not be available in idle mode, the criterion i_{L}<i_{IDLE} may be evaluated using the drain-source voltage VDS (which is approximately proportional to i_{L}, i.e. V_{DS}=i_{L}·R_{ON}, wherein R_{ON} denotes the on-resistance of the power transistor T_{L}) across the transistor T_{L} when operating in idle mode. Furthermore, the temperature dT may be assumed to be constant in idle-mode as the monitoring circuit 14 will not provide an updated value. However, this assumption is valid as the low load current (below i_{IDLE}) will not significantly heat up the cable in idle mode.

As can be seen in FIG. 5, the diagnosis mode S2 can only be entered from idle mode. In practice, the smart switch 1 is in diagnosis mode only for a relatively short time to output diagnosis information and then changes back to idle mode provided that the idle mode condition is still fulfilled. In the present example, a High level of the signal S_{DEN} triggers a change into diagnosis mode S2, whereas a Low level of the signal S_{DEN} triggers a change back to idle mode S1 (if the idle mode condition is still fulfilled).

As explained above, the current sense circuit 13 is active in diagnosis mode S2 to enable an output of diagnosis information. The smart fuse function (monitoring circuit 14) remains, however, inactive in diagnosis mode S2 (see FIG. 5, “smart fuse off”). As a result, the time in diagnosis mode (in which i_{GND} is higher than in idle mode) can be very short and thus does not significantly increase the average current consumption.

It is noted that an operation in diagnosis mode S2 is not a prerequisite for the output of diagnosis information. In normal mode S0, an output of diagnosis information is also possible dependent on the level of the signal S_{DEN} in the same way as in the diagnosis mode. However, in diagnosis mode S2 the monitoring circuit 14 (smart fuse function) is inactive which allows to minimize the time with increased current consumption i_{GND}. That is, when the controller 2 (see FIG. 2) regularly polls diagnosis information during idle mode, the smart switch will regularly change into diagnosis mode for a relatively short time but not into normal mode as long as the idle mode condition is fulfilled.

FIG. 5 also shows a fourth mode, which is optional and referred to as sleep mode S3. The smart switch will change into sleep mode S3 when the input signal S_{IN} indicates an active switch-off of the transistor T_{L}. When the input signal S_{IN} signals to switch the transistor T_{L} on again, the smart switch will always change into normal mode S0 first and, as the case may be, subsequently into idle mode if the idle mode condition is met.

FIG. 6 illustrates a modification of the example of FIG. 1. The example of FIG. 6 is the same as the example of FIG. 1 except for the communication interface 17, which is an SPI interface in the depicted example which uses four bus lines MISO, MOSI, SCLK (serial clock), and CSN (Chip Select). The SPI bus is an industry standard and thus not further discussed herein. Of course other serial communication systems may be used instead of SPI. The signals S_{IN} and S_{DEN} are provided by the communication interface 17 in response to receiving respective commands via the SPI bus. Moreover, the diagnosis information is not output via a dedicated pin (as it is the case in the example of FIG. 1). Instead, the diagnosis information may be sent as digital information (data) across the SPI bus upon receiving a request command via the communication interface. It is understood, that in the present example, the signals S_{IN} and S_{DEN} may be represented by digital values stored, e.g. in a register of the communication interface. With regard to the remaining components of the circuit of FIG. 6 reference is made to the above description of FIG. 1.

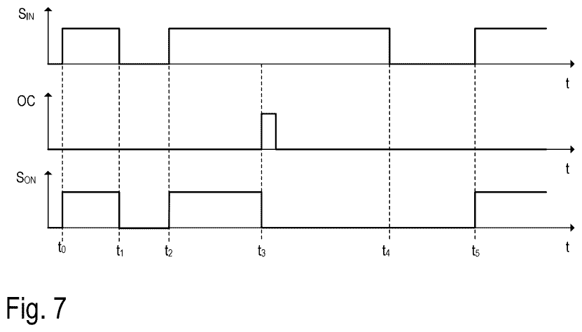

The smart fuse function provided by the monitoring circuit 14 and the control logic 11 is further illustrated by the timing diagrams of FIG. 7. When the input signal S_{IN} (see FIGS. 1 and 6) changes to a high level (indicating a switch-on of the electronic switch T_{L}, see FIG. 7, time instants t₀, t₂ and t₅), the control logic 11 generates the control signal S_{ON} with a High level, which causes the gate driver 12 to charge the gate of the transistor T_{L}. For example, the control signal S_{ON} may be provided by an output of an SR (Set/Reset) latch included in the control circuit 11, wherein a rising edge of the input signal S_{IN} sets the SR latch and a falling edge of the input signal S_{IN} resets the SR latch (see FIG. 7, reset due to a falling edge of S_{IN} at time instant t₁). To trigger a switch-off, the monitoring circuit 14 (the smart fuse function) generates an overcurrent signal OC with a High level, wherein the rising edge of the overcurrent signal OC also triggers a reset of the SR latch and thus causes the control signal S_{ON} to return to a Low level (see FIG. 7, time instant t₃). As discussed above, the overcurrent signal OC is generated based on the load current i_{L} and a given current-time-characteristic curve (e.g. determined by one or more wire parameters such as the wire cross section) used by the monitoring circuit 14. To switch the transistor T_{L} on again, the external controller (cf. FIG. 2) may output a Low level as input signal S_{IN} (FIG. 7, time instant t₄) before the subsequent rising edge of the input signal S_{IN} again sets the SR latch to generate a High level control signal S_{ON} (see FIG. 7, time instant t₅). It is understood that the switching scheme shown of FIG. 7 is merely an illustrative example, and a different scheme may be used dependent on the requirements of the actual application.

The embodiments described above are now summarized. It is understood that the following is not an exhaustive list of technical features but rather an exemplary summary. One embodiment relates to an electronic device (e.g. a packaged semiconductor chip). Accordingly, the device includes an electronic switch (see, e.g. FIG. 1 or 6, transistor T_{L}) having a load current path coupled between an output node and a supply node (see, e.g. FIGS. 1 and 6, chip pins OUT and VS) and configured to connect or disconnect the output node and the supply node in accordance with a control signal. The device further includes a control circuit configured to generate the control signal based on an input signal (see, e.g. FIG. 1, signal S_{IN} received at chip pin IN), a current sense circuit configured to provide a current sense signal that represents a load current passing through the electronic switch, and a monitoring circuit configured to generate an overcurrent signal based on the current sense signal. The monitoring circuit may implement a smart fuse function and the overcurrent signal is indicative of whether, or not, to disconnect the output node from supply node. The control circuit (and thus the whole smart switch device) is configured to operate in a normal mode, an idle mode, and in a diagnosis mode. The control circuit is configured to change between normal mode and idle mode based on an idle mode condition (see, e.g., FIGS. 1 and 6, evaluation circuit 16), wherein, in idle mode, at least the monitoring circuit and the current sense circuit are inactive. The control circuit is further configured to change between idle mode and diagnosis mode based on a diagnosis enable signal (see, e.g. FIG. 1, signal S_{DEN} received at chip pin DEN), wherein, in diagnosis mode, the monitoring circuit remains inactive while the current sense circuit is active.

The control circuit (see FIGS. 1 and 6, control logic 11) causes/triggers activation and deactivation of certain components/circuits of the device upon a mode change. The monitoring circuit is configured to generate the overcurrent signal based on the current sense signal and at least one wire parameter, which may characterize a wire connected between the output node and an electric load during operation of the device. The at least one wire parameter may include, for example, the wire cross section and a temperature threshold.

In one embodiment, the control circuit may be configured to change from diagnosis mode into normal mode when the idle mode condition is not fulfilled anymore. The electronic device may include a diagnosis circuit (see, e.g., FIG. 1 or 6, diagnosis circuit 15) configured to output, dependent on a logic level of the diagnosis enable signal, a signal that is based on the current sense signal. In other embodiments, different information (in addition to current information) may be output as diagnosis information.

In one embodiment, the monitoring circuit may be configured to estimate a property of the wire, wherein the overcurrent signal depends on the estimated property. The estimated property of the wire may represent a temperature difference between a wire temperature and ambient temperature (cf. FIGS. 3 and 4). The estimated property may be stored in a register of the monitoring circuit, wherein the register value is lost/reset when changing to idle mode because the monitoring circuit is inactive in idle mode. In one embodiment, the control circuit may be configured to restore, when changing to normal mode, the register value of the register.

Dependent on the actual implementation, the idle mode condition may depend on one or more criteria. In one embodiment, the idle mode conditions is fulfilled if the load current is below a given current threshold (first criterion) and at least one of the following additional criteria are met: the electronic switch is switched on, a temperature of the electronic switch is below a given temperature threshold. The relevant criteria may be fixed for a specific application, i.e. the idle mode condition is fulfilled if a preset criterion or combination of criteria are met.

The control circuit may be configured to cause a transition from normal mode to idle mode based on the idle mode condition but not before having remained in normal mode for a defined time period (e.g. 100 ms or more). In some embodiments, the control circuit may be configured to change from normal mode to idle mode when the idle mode condition is fulfilled for a defined time period.

Another embodiment relates to a method for operating an electronic device as an electronic fuse. Accordingly, the method includes generating a control signal based on an input signal and connecting/disconnecting an output node and a supply node of the electronic device in accordance with the control signal using an electronic switch (see, e.g. FIGS. 1, 6, and 7). The method further includes: generating, using a current sense circuit, a current sense signal that represents a load current passing through the electronic switch (see, e.g., FIGS. 1 and 6, current sense circuit 13); monitoring the load current, using a monitoring circuit and based on the current sense signal (see, e.g., FIGS. 1 and 6, monitoring circuit 14); and generating an overcurrent signal based on the current sense signal, wherein the overcurrent signal indicates whether, or not, to disconnect the output node from the supply node (see also timing diagram of FIG. 7). The electronic device is configured to operate in a normal mode, an idle mode, and in a diagnosis mode (see FIG. 5, modes S0-S2), wherein the method includes initiating a change between normal mode and idle mode based on an idle mode condition (see, e.g. FIGS. 1 and 6, evaluation circuit 16), wherein, in idle mode, at least the monitoring circuit and the current sense circuit are deactivated, and initiating a change between idle mode and diagnosis mode based on a diagnosis enable signal, wherein, in diagnosis mode, the monitoring circuit remains inactive while the current sense circuit is active.

Having described several embodiments, it is noted that the technical features and elements which are described with regard to different embodiments may be combined to create further embodiments. It is understood that alterations and/or modifications may be made to the examples described herein without departing from the spirit and scope of the appended claims. For example, it is understood that logic levels may be inverted dependent on the actual implementation of logic circuits. That is, a High level in one embodiment may have the same meaning and purpose as a Low level in another embodiment and vice versa. In particular regard to the various functions performed by the above described components or structures (units, circuit components, devices, circuits, systems, etc.), the terms (including a reference to a “means”) used to describe such components are intended to correspond—unless otherwise indicated—to any component or structure, which performs the specified/intended function of the described component (e.g., that is functionally equivalent), even though not structurally equivalent to the described structure, which performs the function in the exemplary implementations of the invention described herein.

1: An electronic device comprising:
an electronic switch having a load current path coupled between an output node and a supply node and configured to connect or disconnect the output node and the supply node in accordance with a control signal;
a control circuit configured to generate the control signal based on an input signal;
a current sense circuit configured to provide a current sense signal that represents a load current passing through the electronic switch; and
a monitoring circuit configured to receive the current sense signal and to generate an overcurrent signal based on the current sense signal, the overcurrent signal being indicative of whether to disconnect the output node from supply node; and
wherein the control circuit is configured to operate in a normal mode, in an idle mode, and in a diagnosis mode,
wherein the control circuit is configured to change between the normal mode and the idle mode based on an idle mode condition (IDL), wherein, in the idle mode, at least the monitoring circuit and the current sense circuit are inactive, and
wherein the control circuit is configured to change between the idle mode and the diagnosis mode based on a diagnosis enable signal, wherein, in the diagnosis mode, the monitoring circuit remains inactive while the current sense circuit is active.

2: The device of claim 1,
wherein the monitoring circuit is configured to determine an overcurrent signal based on the current sense signal and at least one wire parameter.

3: The device of claim 2,
wherein the wire parameter characterizes a wire connected between the output node and an electric load during operation of the device.

4: The device of claim 1,
wherein the control circuit is configured to change from the diagnosis mode into the normal mode when the idle mode condition is not fulfilled anymore.

5: The device of claim 1, further comprising:
a diagnosis circuit configured to output, dependent on a logic level of the diagnosis enable signal, a signal that is based on the current sense signal.

6: The device of claim 3,
wherein the monitoring circuit is configured to estimate a property of the wire, wherein the overcurrent signal depends on the estimated property.

7: The device of claim 3,
wherein the control circuit is configured to restore, when changing to the normal mode, a register value of a register of the monitoring circuit, the register value representing an estimated property of the wire.

8: The device of claim 7,
wherein the register value is reset when the monitoring circuit becomes inactive due to a change into the idle mode.

9: The device of claim 6,
wherein the estimated property of the wire represents a temperature difference between a wire temperature and ambient temperature.

10: The device of claim 1,
wherein the idle mode condition is fulfilled if at least the following criteria are met: the load current is below a given current threshold, the electronic switch is switched on, and a temperature of the electronic switch is below a given temperature threshold.

11: The device of claim 10,
wherein the idle mode condition is fulfilled if a preset combination of the criteria are met.

12: The device of claim 1,
wherein the control circuit is configured to change from the normal mode to the idle mode based on the idle mode condition but not before remaining in the normal mode for a defined time period.

13: The device of claim 1,
wherein the control circuit is configured to change from the normal mode to the idle mode when the idle mode condition is fulfilled for a defined time period.

14: A method comprising:
generating a control signal based on an input signal;
connecting and disconnecting an output node and a supply node of an electronic device in accordance with the control signal using an electronic switch;
generating, by a current sense circuit, a current sense signal that represents a load current passing through the electronic switch;
monitoring the load current, by a monitoring circuit and based on the current sense signal, and generating an overcurrent signal based on the current sense signal, the overcurrent signal being indicative of whether to disconnect the output node from the supply node; and
wherein the electronic device is configured to operate in a normal mode, in an idle mode, and in a diagnosis mode,
wherein a change between the normal mode and the idle mode is initiated based on an idle mode condition, wherein, in the idle mode, at least the monitoring circuit and the current sense circuit are inactive, and
wherein a change between the idle mode and the diagnosis mode is initiated based on a diagnosis enable signal, wherein, in the diagnosis mode, the monitoring circuit remains inactive while the current sense circuit is active.

15: The method of claim 14, wherein a change from the normal mode to the idle mode is not performed before operating in the normal mode for a defined time period.
